(19) United States
(12) Patent Application Publication
(10) Pub. No.: US 2005/0148119 A1
(43) Pub. Date: Jul. 7, 2005

(54) Method of manufacturing thin film transistor, method of manufacturing flat panel display, thin film transistor, and flat panel display

(75) Inventor: Takashi Fujimura, Kanagawa-Ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/028,650

(22) Filed: Jan. 5, 2005

Related U.S. Application Data
(62) Division of application No. 10/627,622, filed on Jul. 28, 2003, now abandoned.

(30) Foreign Application Priority Data
Jul. 30, 2002 (JP) 2002-220911

(51) Int. Cl. H01L 29/04; H01L 29/10; H01L 31/036; H01L 31/0376; H01L 31/20; H01L 21/20; H01L 27/108; H01L 29/76; H01L 29/94; H01L 31/119

(52) U.S. Cl. 438/141; 257/59

(57) ABSTRACT

A method of manufacturing a thin film transistor and a method of manufacturing a flat panel display without increasing the number of heat treatment steps, and a thin film transistor and a flat panel display obtained by such methods are disclosed. A semiconductor region having an island shape is formed on an insulating substrate. A gate electrode is formed above the semiconductor region with a gate dielectric film being located therebetween. An impurity is implanted to the semiconductor region using the gate electrode as a mask, thereby forming source and drain regions in a self-aligned manner at both sides of a channel region. An interlayer dielectric film is formed on the gate electrode and the gate dielectric film. Thereafter, a step of activating the impurity and a step of burning the interlayer dielectric film are simultaneously performed in a single heat treatment step.

### CROSS-REFERENCES TO RELATED APPLICATIONS

This application is a division of and claims the benefit of priority under 35 USC §120 from U.S. application Ser. No. 10/627,622, filed Jul. 28, 2003 and is based upon and claims the benefit of priority under 35 USC §119 from Japanese Patent Application No. 2002-220911, filed Jul. 30, 2002, the entire contents of which are incorporated herein by reference.

### FIELD OF THE INVENTION

The present invention relates to a method of manufacturing a thin film transistor, a method of manufacturing a flat panel display, a thin film transistor, and a flat panel display.

### BACKGROUND OF THE INVENTION

Recently, there has been active research and development concerning a thin film transistor liquid crystal display (TFT-LCD) incorporating a driving circuit, in which a high definition liquid crystal display using a polycrystalline silicon layer and periphery circuits are formed on a single substrate.

A typical method of manufacturing such a TFT-LCD incorporating a driving circuit is as follows.

First, in order to form a channel layer of a TFT, an amorphous silicon (a-Si) layer is formed on a substrate by the CVD method. Then, in order to improve the characteristics of the TFT, the a-Si layer is annealed by the use of an energy beam such as an excimer laser, thereby forming a polycrystalline silicon (p-Si) layer. The p-Si layer is patterned into a predetermined shape through a photolithography step and an etching step. Then, a gate dielectric film is formed by the CVD method so as to cover the p-Si layer. Thereafter, a metal layer is deposited on the gate dielectric film, and is pattered to form a gate electrode. Subsequently, an impurity (boron or phosphorous) is implanted to the p-Si layer using the gate electrode as a mask. Next, the implanted impurity is activated through a thermal annealing step in order to form source and drain regions. Then, an interlayer dielectric film is formed by the CVD method so as to cover the gate electrode, etc. Subsequently, the interlayer dielectric film is etched to form contact holes to connect to the source and drain regions. Thereafter, a metal layer to serve as signal lines, etc., is deposited and patterned to form source and drain electrodes, which are connected to the source and drain regions via the contact holes. Then, a step of forming a signal line electrically connecting to the source electrode, etc. is performed in order to complete a TFT-LCD incorporating a driving circuit.

There is a demand for further miniaturization of wiring such as the aforementioned signal lines in order to improve the degree of integration of the above-described periphery circuits. However, as can be understood from the above descriptions, the TFT portion is formed by laminating various layers. Accordingly, if the wiring is scaled down further, the possibility of causing disconnection at a step portion in an underlying layer is increased, thereby decreasing the yield.

In order to overcome this problem, a method is proposed in which the interlayer dielectric film is coated by the use of a coater (coating method). According to this method, it is possible to flatten the surface of the interlayer dielectric film. That is, according to this method, even if there is a step portion on the base layer, there is no step portion on the surface of the interlayer dielectric film, resulting in that it is possible to prevent a disconnection of wiring formed on the surface of the interlayer dielectric film. However, when an interlayer dielectric film is formed by the use of a coater in accordance with the above-described coating method, it is necessary to burn the workpiece at a temperature of about 400° C. Therefore, as can be understood from the above description, two heat treatment steps, i.e., a step of activating an impurity, and a step of burning the workpiece, are necessary. Generally, when a heat treatment step is performed, cracks, etc. are generated in laminated layers due to the expansion and shrinkage of the substrate. As such, an increase in number of thermal treatment steps would increase the number of occurrences of failures. Of course, the increase in number of heat treatment steps would thus directly result in a decrease in productivity.

### SUMMARY OF THE INVENTION

The present invention is proposed in view of the above-described problem, and it is an object of the present invention to provide a method of manufacturing a thin film transistor and a method of manufacturing a flat panel display, in which the number of heat treatment steps required is not increased. It is another object of the present invention to provide a thin film transistor and a flat panel display, in which the number of failures caused by cracks, etc. are reduced as much as possible.

A method of manufacturing a thin film transistor according to the present invention includes: forming a semiconductor region having an island shape on an insulating substrate; forming a gate electrode above the semiconductor region with a gate dielectric film being provided therebetween; implanting an impurity to the semiconductor region using the gate electrode as a mask, in order to form source and drain regions in a self-aligned manner at both sides of a channel region; forming an interlayer dielectric film on the gate electrode and the gate dielectric film; and simultaneously activating the impurity and burning the interlayer dielectric film through a single heat treatment.

A method of manufacturing a flat panel display according to the present invention is as follows. With respect to a method of manufacturing a flat panel display including pixels arranged in a matrix form, and displaying an image by individually turning on or off a transistor of each pixel, the method including a method of manufacturing the transistor, including: forming a semiconductor region having an island shape on an insulating substrate; forming a gate electrode above the semiconductor region with a gate dielectric film being provided therebetween; implanting an impurity to the semiconductor region using the gate electrode as a mask, in order to form source and drain regions in a self-aligned manner at both sides of a channel region; forming an interlayer dielectric film on the gate electrode and the gate dielectric film; and simultaneously activating the impurity and burning the interlayer dielectric film through a single heat treatment.

A thin film transistor according to the present invention includes: an insulating substrate; a channel region serving as a central portion of a semiconductor layer having an island shape formed on the insulating substrate; a pair of source and drain regions formed at both sides of the channel region in the semiconductor layer; a desorption preventing layer formed to cover at least the channel region and the source and drain regions for preventing hydrogen terminating dangling bonds of the semiconductor layer from desorbing from the dangling bonds; and an interlayer dielectric film formed on the desorption preventing layer.

A flat panel display according to the present invention is as follows. With respect to a flat panel display including pixels arranged in a matrix form, and displaying an image by individually turning of or off a transistor of each pixel, the transistor includes: an insulating substrate; a channel region serving as a central portion of a semiconductor layer having an island shape formed on the insulating substrate; a pair of source and drain regions formed at both sides of the channel region in the semiconductor layer; a desorption preventing layer formed to cover at least the channel region and the source and drain regions for preventing hydrogen terminating dangling bonds of the semiconductor layer from desorbing from the dangling bonds; and an interlayer dielectric film formed on the desorption preventing layer.

### BRIEF DESCRIPTION OF THE DRAWINGS

FIGS. 1(a)-1(c) are sectional views showing several of the steps of a method of manufacturing a first TFT in accordance with the first embodiment of the present invention.

FIGS. 2(a) and 2(b) are sectional views showing the steps, which are subsequent to the steps shown in FIG. 1(a)-1(c), of the method of manufacturing the first TFT in accordance with the first embodiment of the present invention.

FIG. 3 is a graph showing the relationship between the heat treatment temperature and the sheet resistance value when the step of activating an impurity and the step of burning an interlayer dielectric film are performed in a single heat treatment.

FIGS. 4(a)-4(c) are sectional views showing the steps of a method of manufacturing a second TFT in accordance with the second embodiment of the present invention.

FIG. 5 is a sectional view showing the step of the method of manufacturing the second TFT in accordance with the second embodiment of the present invention, the step being subsequent to the steps shown in FIGS. 4(a)-4(c).

FIG. 6 is a graph showing the result of the comparison between the on-current values of the first TFT and the second TFT.

FIG. 7 shows an example of a circuit diagram of a main portion of a liquid crystal display incorporating the TFTs of the present invention.

### DESCRIPTION OF THE EMBODIMENTS

Hereinafter, the embodiments of the present invention will be described with reference to the accompanying drawings.

First, a liquid crystal display according to the present invention will be briefly described below.

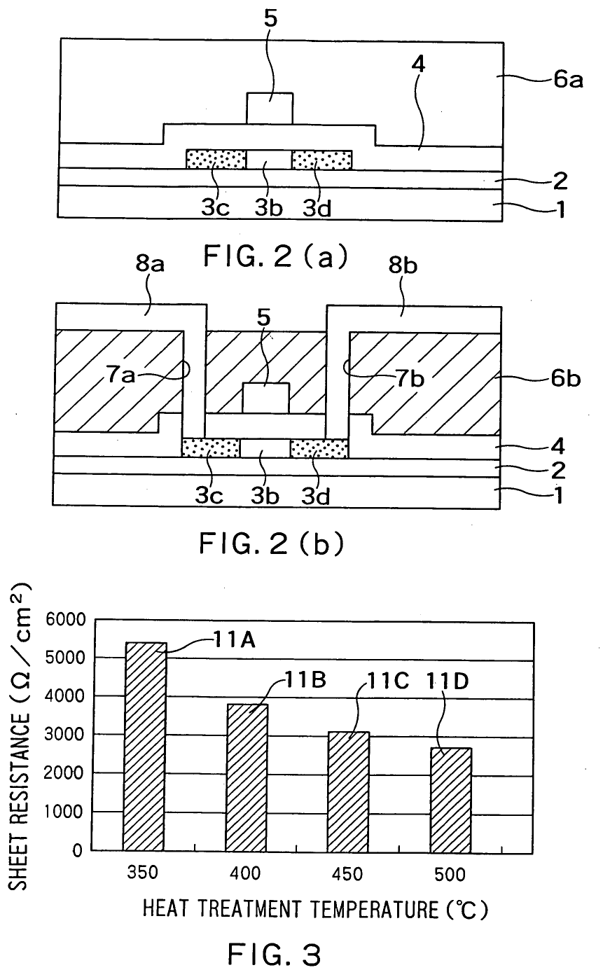

A liquid crystal display according to the present invention is a thin film transistor liquid crystal display (TFT-LCD) incorporating a driving circuit, in which a high definition liquid crystal display and periphery circuits are formed on a single substrate. An example of the TFT portion thereof is shown in FIG. 2(b).

A polycrystalline silicon (poly silicon) layer 3b to serve as a channel layer is formed on an insulating substrate 1 with an undercoat layer 2 being located therebetween. A gate electrode 5 is formed above the polycrystalline silicon layer 3b with a gate dielectric film 4 being located therebetween. Further, source and drain regions 3c and 3d are formed at both sides of the polycrystalline silicon layer 3b. Source and drain electrodes 8a and 8b are connected to the source and drain regions 3c and 3d via the gate dielectric film 4 and the interlayer dielectric film 6b. The reference numerals 7a and 7b denote contact holes.

Hereinafter, a method of manufacturing a flat panel display according to an embodiment of the present invention will be described with reference to the accompanying drawings.

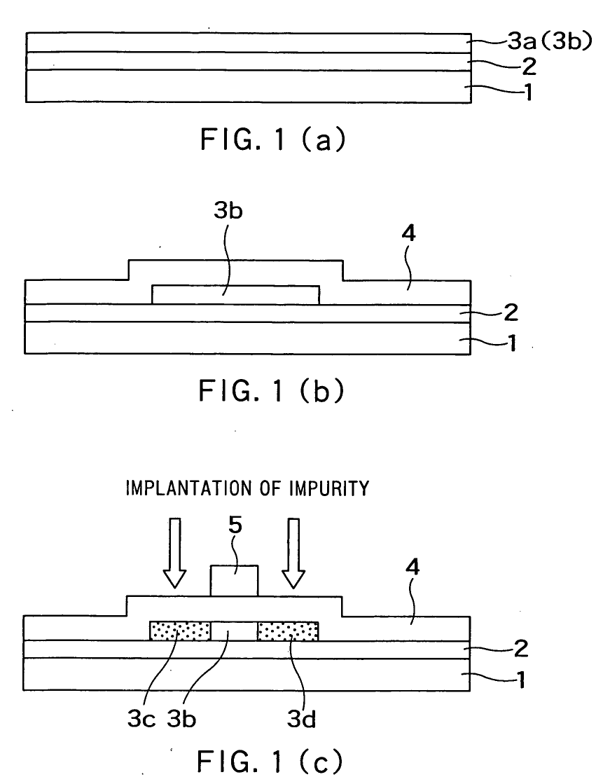

FIGS. 1(a)-1(c) and 2(a)-2(b) are sectional views showing the steps of a method of manufacturing a thin film transistor (first TFT) according to the first embodiment of the present invention.

The first TFT corresponds to a pixel of an array substrate of a TFT-LCD, or a TFT formed in a periphery circuit of the array substrate.

Hereinafter, the steps of manufacturing the first TFT will be described in detail.

First, as can be understood from FIG. 1(a), an undercoat layer 2 is formed on an insulating substrate 1 of non-alkali glass, of the size which is 400 mm long and 500 mm wide. The undercoat layer 2 has a two-layer structure formed by sequentially depositing a silicon nitride (SiN) layer and a silicon oxide (SiO₂) layer by the plasma CVD method. Subsequently, an amorphous silicon layer 3a having a thickness of, e.g., 50 nm, is formed on the undercoat layer 2. Then, annealing is performed on the workpiece at a temperature of 500° C. for an hour so as to evaporate hydrogen within the amorphous silicon layer 3a to decrease the hydrogen concentration. Thereafter, the amorphous silicon layer 3a is annealed by the use of an excimer laser having a wavelength of 308 nm (XeCl) so that the layer becomes a polycrystalline silicon layer 3b. The laser beam for performing crystallization can be KrF or ArF.

Then, as can be understood from FIG. 1(b), the polycrystalline silicon layer 3b is patterned to have an island shape. Thereafter, a gate dielectric film 4 of silicon oxide (SiO₂) is deposited by the plasma CVD method so as to cover the polycrystalline silicon layer 3b.

Next, as can be understood from FIG. 1(c), a polycrystalline silicon layer, in which phosphorous or the like is doped, is deposited on the entire surface of the gate dielectric film 4 and patterned so as to form a gate electrode 5. At the same time, gate lines and auxiliary capacitance lines, etc. are also formed. Besides polycrystalline silicon, the material of the gate electrode 5 can be a high-melting-point metal such as molybdenum (Mo), tantalum (Ta), etc. Then, a dopant (impurity) is implanted to the polycrystalline silicon layer 3b in a self-aligned manner using the gate electrode 5 as a mask by the ion doping method, in order to form source and drain regions 3c and 3d. Then, a hydrogen plasma treatment is performed by the plasma CVD method in order to terminate the dangling bonds of the polycrystalline silicon layer 3b.

Next, as can be understood from FIG. 2(a), an interlayer dielectric film 6a containing silicon atoms and oxygen atoms (Si—O) as major components is applied by a coater to cover the gate electrode 5 (coating method). The material of the interlayer dielectric film 6a can be an organic insulating material or an inorganic insulating material. Thereafter, a heat treatment is performed at a temperature of 350, 400, 450, or 500° C. for an hour in order to activate the impurity having been implanted to the polycrystalline silicon layer 3b, and at the same time to burn the interlayer dielectric film 6a. In other words, the step of activating the impurity and the step of burning the interlayer dielectric film 6a are performed through a single heat treatment. It is preferable that the burning be performed at the lowest possible temperature selected from the above-described temperatures for performing the activation of impurity. In this way, adverse effects of the heat treatment on the device can be suppressed. As can be understood from FIG. 2(b), after the burning step, the source and drain regions 3c and 3d and an interlayer dielectric film 6b are formed. That is, the TFT and the interlayer dielectric film can be simultaneously formed. In this way, an interlayer dielectric film can be formed through a single heat treatment step, i.e., without increasing the number of heat treatment steps as compared with the process using the CVD method.

Next, as can be understood from FIG. 2(b), contact holes 7a and 7b reaching the source and drain regions 3c and 3d are formed in the interlayer dielectric film 6b. Then, a metal, such as aluminum (Al) is filled in the contact holes 7a and 7b by the sputtering method, and at the same time, deposited on the interlayer dielectric film 6b. Thereafter, the portions of the metal on the interlayer dielectric film 6b are patterned. In this way, as shown in FIG. 2(b), source and drain electrodes 8a and 8b connecting to the source and drain regions 3c and 3d via the contact holes 7a and 7b are formed. At this time, the wiring lines such as signal lines (not shown) are also formed on the interlayer dielectric film 6b.

FIG. 3 is a histogram showing the relationship between the heat treatment temperature and the sheet resistance value of the cannel portion when the heat treatment step covering the step of activating impurity and the step of burning the interlayer dielectric film is performed for an hour at a temperature of 350, 400, 450, and 500° C. This histogram was prepared based on the actual results of the experiment performed by the present inventor. The sheet resistance values represented by the vertical axis of the histogram were measured at the channel section of the first TFT. Of course, a lower value represents a better result. Since it is expected that the lower the heat treatment temperature is, the lower the impurity activation rate becomes, the ion doping conditions were changed in accordance with each heat treatment temperature.

As can be understood from 11A to 11D each representing a sheet value in FIG. 3, the lower the heat treatment temperature was (from 500 toward 450, 400, and 350° C.), the higher the sheet resistance became. As indicated by the graph bar 11A, when the temperature was 350° C., the sheet resistance value was about 7,000 (Ω/cm²) or less. This value shows that the device is applicable to actual use. The following can be understood from this fact: when a heat treatment for activating an impurity or for burning an interlayer dielectric film is performed, the heat treatment temperature should be as low as possible in order to reliably prevent failure-inducing aspects such as cracks; according to the present invention, it is possible to obtain a TFT having a sheet resistance value applicable to the actual use even if a heat treatment is performed at such a low temperature. It should be noted that the sheet resistance value in the case of the heat treatment at 350° C. shown by the graph 11A can be lowered further by optimizing the ion doping acceleration voltage at the time of the implantation of impurity, the thickness of the gate dielectric film 4, the thickness of the polycrystalline silicon layer 3b, etc.

Next, a comparative example will be described below in order to verify the effects of the above-described embodiment. In the comparative example, a sheet resistance value was measured in the case where the two heat treatments, one for the step of activating impurity and one for the step of burning interlayer dielectric film, were performed separately. Specifically, after a dopant is implanted to a polycrystalline silicon layer by the ion doping method, the impurity was activated at 500° C. for an hour, and then an interlayer dielectric film was burned at 400° C. and for an hour. The sheet resistance value in this case was about 2,200 (Ω/cm²). Thus, the effect of this embodiment has been verified.

As described above, according to the first embodiment of the present invention, it is possible to form an interlayer dielectric film by the coating method, with the occurrence of failure-inducing factors such as cracks being suppressed, by simultaneously performing the step of activating an impurity implanted to a polycrystalline silicon layer and the step of burning an interlayer dielectric film.

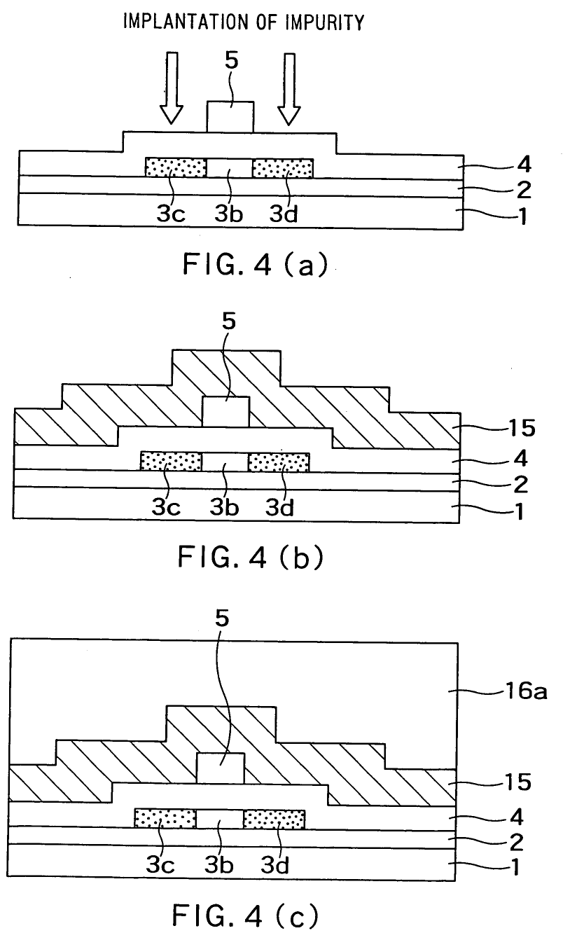

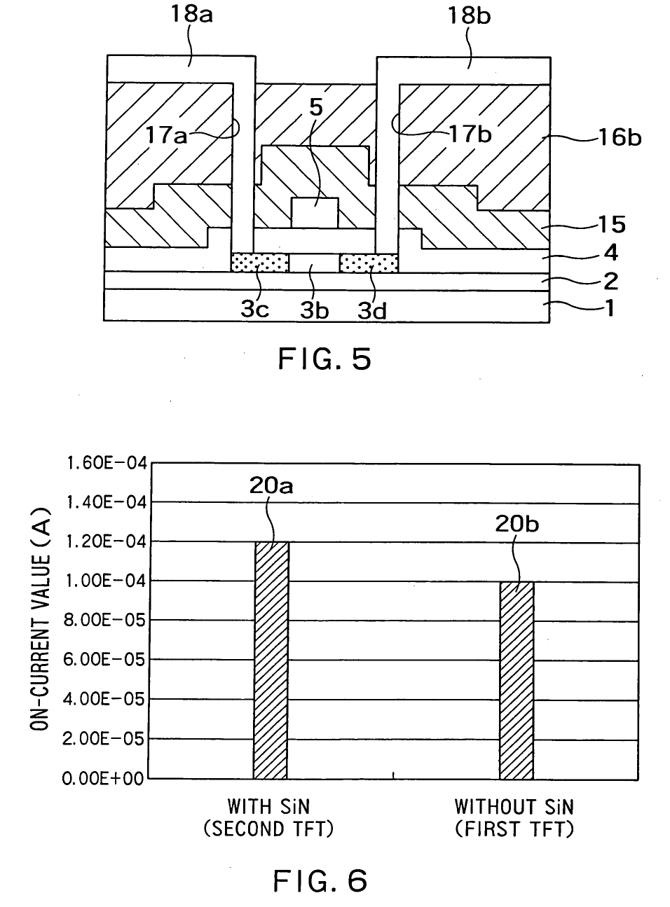

FIGS. 4(a)-4(c) and 5 relate to the second embodiment of the present invention, and are sectional views of the steps of a method of manufacturing another kind of TFT (second TFT). In FIGS. 4(a)-4(c) and 5, the elements common to those in FIGS. 1(a)-1(c) and 2 have the same reference numerals, and the explanation thereof is omitted. The difference between the second embodiment and the first embodiment lies in that a silicon nitride layer is formed as the base layer of the interlayer dielectric film in the second embodiment.

Hereinafter, the process of manufacturing the second TFT will be described in detail.

FIG. 4(a) shows the same step as FIG. 1(c). That is, after the steps shown in FIGS. 1(a) and 1(b) of the first embodiment are performed, an impurity is implanted to the polycrystalline silicon layer 3b using the gate electrode 5 as a mask to form the source and drain regions as shown in FIG. 4(a) in a self-aligned manner.

Next, as can be understood from FIG. 4(b), a hydrogen plasma treatment is performed by the plasma CVD method in order to terminate dangling bonds of the polycrystalline silicon layer 3b. Thereafter, as shown in FIG. 4(b), a silicon nitride (SiN) layer 15 having a thickness of, e.g., 200 nm, is formed so as to cover the gate electrode 5.

Then, as shown in FIG. 4(c), an interlayer dielectric film 16a is formed over the entire surface of the silicon nitride layer 15. Subsequently, a thermal treatment to simultaneously perform the step of activating the impurity having been implanted to the polycrystalline silicon layer 3b and the step of burning the interlayer dielectric film 16a is performed at 400° C. and for an hour. As a result, source and drain regions 3c and 3d are formed in the polycrystalline silicon layer 3b, and the interlayer dielectric film 16b is formed, as shown in FIG. 5.

Thereafter, through the same steps as those in the first embodiment, a polycrystalline silicon TFT as shown in FIG. 5 can be obtained. Specifically, as can be understood from FIG. 5, the interlayer dielectric film 16b is etched to form contact holes 17a and 17b reaching the source and drain regions 3c and 3d. Then, source and drain electrodes 18a and 18b of aluminum are formed.

FIG. 6 is a graph showing on-current values (drain current values) of the second TFT manufactured in accordance with the second embodiment, and the first TFT manufactured in accordance with the first embodiment. Of course, it is preferable that the on-current value be as high as possible.

As indicated by the graph bar 20a of FIG. 6, the on-current value 1.2×10⁻⁴ (A) of the second TFT, which includes the silicon nitride layer, is greater than the on-current value 1.0×10⁻⁴ (A) of the first TFT, which includes no silicon nitride layer, indicatedby the graphbar 20b. The reason for this is as follows.

As can be understood from FIG. 2(b), when no silicon nitride layer is formed under the interlayer dielectric film 6b, i.e., on the polycrystalline silicon layer 3b, the hydrogen atoms terminating the dangling bonds of the polycrystalline silicon layer 3b are desorbed during the annealing at 400° C. (heat treatment). That is, the hydrogen atoms terminating the dangling bonds of the polycrystalline silicon layer 3b escape to the outside via the upper layer, i.e., the interlayer dielectric film 6b. For this reason, electrons moving through the channel are deemed to be trapped, thereby lowering the on-current.

On the other hand, as can be understood from FIG. 5, when a silicon nitride layer 15 is formed on the polycrystalline silicon layer 3b, the silicon nitride layer 15 serves as a cap layer, thereby preventing the hydrogen atoms from desorbing from the dangling bonds of the polycrystalline silicon layer 3b. Further, since the silicon nitride layer 15 contains a lot of hydrogen therein, the hydrogen is diffused into the polycrystalline silicon layer 3b and further terminates the dangling bonds of the polycrystalline silicon layer 3b. For this reason, it is more difficult for the dangling bonds to trap the electrons moving through the polycrystalline silicon layer 3b of the second TFT including the silicon nitride layer than to trap those of the first TFT including no silicon nitride layer. Thus, as can be understood from FIG. 6, the on-current value of the second TFT is greater than that of the first TFT.

As described above, according to the second embodiment of the present invention, since a silicon nitride layer serving as a cap layer is provided between the polycrystalline silicon layer and the interlayer dielectric film, it is possible to prevent hydrogen atoms terminating the dangling bonds from desorbing. Further, since the hydrogen atoms contained in the silicon nitride layer are diffused into the polycrystalline silicon layer, it is possible to terminate the dangling bonds of the polycrystalline silicon layer further, thereby forming a TFT having a greater on-current value.

Although a method of manufacturing a flat panel display has been applied to a liquid crystal display in the above-described first and second embodiments, the present invention can be applied to an organic EL display. That is, it is possible to manufacture a flat panel display such as a liquid crystal display or an organic EL display incorporating a transistor of the above-described first or second embodiment.

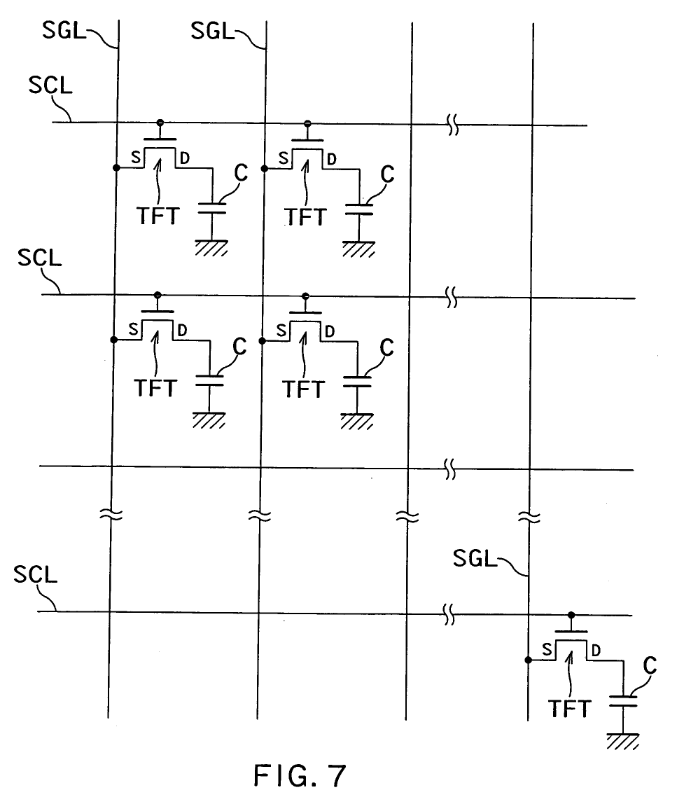

FIG. 7 shows an example of a liquid crystal display. Since this kind of liquid crystal display is well known, detailed description will not be made, but briefly, the characteristic features thereof are as follows. The liquid crystal display has a plurality of pixels located in a matrix form. An image is displayed by turning on and off the individual transistors of the pixels. In FIG. 7, signal lines SGL are placed vertically, and scanning lines SCL are placed horizontally. A transistor TFT is provided to each intersection of a vertical line and a horizontal line. The gate of each transistor TFT is connected to a scanning line SGL, and the source is connected to a signal line SCL, respectively. When the transistor TFT is in an ON state, signals transmitted through the signal line SGL are accumulated to a capacitance C through the transistor TFT.

Although the structure of a typical organic EL display is different from that of a liquid crystal display, the structure is well known. Accordingly, a description and a drawing of organic EL display have been omitted. It is possible to use a TFT of the first embodiment or the second embodiment of the present invention in an organic EL display.

According to the present invention, the step of activating an impurity implanted to a semiconductor layer and the step of burning a coated interlayer dielectric film are simultaneously performed in a single heat treatment step. Accordingly, the number of heat treatment steps can be reduced. Thus, it is possible to form an interlayer dielectric film by the coating method with the occurrences of failure-inducing factors such as cracks in the layers deposited on a substrate being suppressed as much as possible.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A method of manufacturing a thin film transistor comprising:
forming a semiconductor region having an island shape on an insulating substrate;
forming a gate electrode above the semiconductor region with a gate dielectric film being provided therebetween;
Implanting an impurity to the semiconductor region using the gate electrode as a mask, in order to form source and drain regions in a self-aligned manner at both sides of a channel region;
forming an interlayer dielectric film on the gate electrode and the gate dielectric film; and
simultaneously activating the impurity and burning the interlayer dielectric film through a single heat treatment.

2. The method of manufacturing a thin film transistor according to claim 1, wherein the semiconductor region having an island shape is formed on an undercoat layer formed on the insulating substrate.

3. The method of manufacturing a thin film transistor according to claim 2, wherein the undercoat layer has a two-layer structure including a silicon nitride layer and a silicon oxide layer.

4. The method of manufacturing a thin film transistor according to claim 1, wherein the semiconductor region having an island shape is formed by:
forming an amorphous silicon layer;
causing the amorphous silicon layer to become a polycrystalline silicon layer by the use of an excimer layer; and
patterning the polycrystalline silicon layer.

5. The method of manufacturing a thin film transistor according to claim 4, wherein the amorphous silicon layer is caused to become the polycrystalline silicon layer after the amorphous silicon layer is annealed to evaporate hydrogen, thereby lowering a hydrogen concentration.

6. The method of manufacturing a thin film transistor according to claim 4, wherein after implanting the impurity to form the source and drain regions, a hydrogen plasma treatment by a plasma CVD method is performed to terminate dangling bonds of the polycrystalline silicon layer with hydrogen.

7. The method of manufacturing a thin film transistor according to claim 1, wherein the interlayer dielectric film is formed of an organic insulating material or an inorganic insulating material containing silicon atoms and oxygen atoms as major components.

8. The method of manufacturing a thin film transistor according to claim 7, wherein the burning is performed for an hour at a temperature selected from the group consisting of 350° C., 400° C., 450° C., and 500° C.

9. The method of manufacturing a thin film transistor according to claim 6, wherein a second silicon nitride layer for preventing hydrogen terminating the dangling bonds from desorbing from the dangling bonds is formed as an underlying layer of the interlayer dielectric film.

10. The method of manufacturing a thin film transistor according to claim 9, wherein the second silicon nitride layer has a thickness of 200 nm.

11. The method of manufacturing a thin film transistor according to claim 10, wherein the heat treatment is performed at 400° C. for an hour.

12. A method of manufacturing a flat panel display including pixels arranged in a matrix form, and displaying an image by individually turning on or off a transistor of each pixel, the method including a method of manufacturing the transistor, comprising:
forming a semiconductor region having an island shape on an insulating substrate;
forming a gate electrode above the semiconductor region with a gate dielectric film being provided therebetween;
implanting an impurity to the semiconductor region using the gate electrode as a mask, in order to form source and drain regions in a self-aligned manner at both sides of a channel region;
forming an interlayer dielectric film on the gate electrode and the gate dielectric film; and
simultaneously activating the impurity and burning the interlayer dielectric film through a single heat treatment.

13. The method of manufacturing a thin film transistor according to claim 12, wherein the semiconductor region having an island shape is formed on an undercoat layer formed on the insulating substrate.

14. The method of manufacturing a thin film transistor according to claim 12, wherein the undercoat layer has a two-layer structure including a silicon nitride layer and a silicon oxide layer.

15. The method of manufacturing a thin film transistor according to claim 12, wherein the semiconductor region having an island shape is formed by:
forming an amorphous silicon layer;
causing the amorphous silicon layer to become a polycrystalline silicon layer by the use of an excimer layer; and
patterning the polycrystalline silicon layer.

16. The method of manufacturing a thin film transistor according to claim 15, wherein the amorphous silicon layer is caused to become the polycrystalline silicon layer after the amorphous silicon layer is annealed to evaporate hydrogen, thereby lowering a hydrogen concentration.

17. The method of manufacturing a thin film transistor according to claim 15, wherein after implanting the impurity to form the source and drain regions, a hydrogen plasma treatment by a plasma CVD method is performed to terminate dangling bonds of the polycrystalline silicon layer with hydrogen.

18. The method of manufacturing a thin film transistor according to claim 12, wherein the interlayer dielectric film is formed of an organic insulating material or an inorganic insulating material containing silicon atoms and oxygen atoms as major components.

19. The method of manufacturing a thin film transistor according to claim 18, wherein the burning is performed for an hour at a temperature selected from the group consisting of 350° C., 400° C., 450° C., and 500° C.

20. The method of manufacturing a thin film transistor according to claim 17, wherein a second silicon nitride layer for preventing hydrogen terminating the dangling bonds from desorbing from the dangling bonds is formed as an underlying layer of the interlayer dielectric film.

21. The method of manufacturing a thin film transistor according to claim 20, wherein the second silicon nitride layer has a thickness of 200 nm.

22. The method of manufacturing a thin film transistor according to claim 21, wherein the heat treatment is performed at 400° C. for an hour.

23. (canceled)

24. (canceled)
